(19) United States
(12) Patent Application Publication
(10) Pub. No.: US 2021/0368628 A1
(43) Pub. Date: Nov. 25, 2021

(54) COPPER CLAD LAMINATE AND PRINT CIRCUIT BOARD COMPRISING THE SAME

(71) Applicant: Circuit Foil Luxembourg, Sàrl, Wiltz, Luxembourg (LU)

(72) Inventors: Thomas DEVAHIF, Wiltz, Luxembourg (LU); Michel STREEL, Wiltz, Luxembourg (LU); Zainhia KAIDI, Wiltz, Luxembourg (LU)

(73) Assignee: Circuit Foil Luxembourg, Sàrl, Wiltz, Luxembourg (LU)

(21) Appl. No.: 16/321,620

(22) PCT Filed: Jul. 31, 2017
(86) PCT No.: PCT/EP2017/069316

§ 371 Date: Jan. 29, 2019

(51) Int. Cl. H05K 3/02; H05K 3/38; C08L 71/12; B32B 15/08; B32B 15/20; H05K 1/03; C25D 1/04; C25D 3/38; B32B 27/36; B32B 27/20; B32B 27/26

(52) U.S. Cl. CPC H05K 3/022; B32B 2307/748; C08L 71/12; B32B 15/08; B32B 15/20; H05K 1/0373; C25D 1/04; C25D 3/38; B32B 27/36; B32B 27/20; B32B 27/26; H05K 2203/0307; H05K 2203/0723; B32B 2255/06; B32B 2255/205; B32B 2457/08; B32B 2307/732; B32B 2307/538; H05K 3/384

(57) ABSTRACT

A copper-clad laminate including at least one of a copper layer having a roughened surface is disclosed. The copper-clad laminate is obtained by roughening at least one surface of a base copper layer so as to have a low profile comprising a copper layer having a thickness of from 5 μm to 70 μm and a resin layer on the copper layer, wherein a peeling strength between the copper layer and the resin layer is more than 0.6 N/mm when the thickness of the copper layer is more than 5 μm, wherein a ten-point mean roughness Sz of the roughened surface is lower than that of the base copper layer.

### BACKGROUND OF THE INVENTION

### Field of the Invention

Exemplary embodiments of the present invention relate to a copper clad laminate and print circuit board comprising the same.

### Description of the Related Art

Printed wiring boards have made significant advances over the past half-century, and are currently used in almost all electronic devices. With a recent increase in the demands for miniaturization and higher performance of electronic devices, high density installation of loaded components or higher frequency of signals has made a progress, and excellent high frequency response for printed wiring boards has been required.

As for boards for a high frequency, a decrease in the transmission loss has been required in order to secure output signal qualities. Transmission loss is mostly formed with dielectric loss caused by a resin (board side) and conductor loss caused by a conductor (copper foil side). Dielectric loss decreases as a dielectric constant of a resin and a dissipation factor decrease. In a high frequency signal, conductor loss is mainly caused by a decrease in a cross-sectional area in which a current flows by a skin effect, that is, a current flows only on a surface of a conductor as a frequency increases, and an increase in the resistance.

Meanwhile, a copper foil or a copper alloy foil (hereinafter, referred to simply as “copper foil”) is widely used for the purpose of a conductor (conductive member or conductive strip). A printed circuit board is manufactured by layering (laminating) a copper foil on a polyphenylene ether (PPE) film or by coating a copper foil with a varnish mainly composed of polyphenylene ether (PPE). Hereinafter, materials such as polyphenylene ether (PPE) film, varnish, or solidified varnish to be used for the printed circuit board are referred as “base material (substrate) for a printed circuit board” or simply as “base material”.

A good adhesion is required between the copper foil and the base material for a printed circuit board. Therefore, the roughening treatment is frequently conducted for a surface of the copper foil to increase an anchoring effect, thereby improving the adhesion strength with the base material for a printed circuit board.

The copper foil is classified into an electro-deposited copper foil and a rolled copper foil according to the manufacturing method therefor. However, the roughening treatment is conducted in similar manner for these two types of copper foils. For example, as a manner of roughening treatment, a manner of applying (depositing) copper in the form of grains on a surface of the copper foil by burnt plating and a manner of selectively etching grain boundaries by using acid are generally used.

As described above, the roughening process can improve the adhesion strength between the copper foil and the base material by providing an anchoring effect. In this case, however, the electrical property of the copper foil becomes worse as the roughness increases. Accordingly, the copper foil having both high adhesion strength and superior electrical properties has been demanded.

### SUMMARY OF THE INVENTION

An object of the present invention is to provide a copper clad laminate having excellent adhesion strength with a resin laminated on a copper layer and having excellent electrical properties with a very low insertion loss.

Another object of the present invention is to provide a printed circuit board and an electronic device comprising the above copper clad laminate.

However, objects of the present invention are not limited to the objects described above, and other objects that are not mentioned will be clearly understood to those skilled in the art from the descriptions provided below.

In accordance with one aspect of the present invention, a copper-clad laminate comprising at least one of a copper layer having a roughened surface which is obtained by roughening at least one surface of a base copper layer so as to have a low profile, comprising a copper layer having a thickness of from 5 μm to 70 μm and a resin layer on the copper layer, wherein a peeling strength between the copper layer and the resin layer is more than 0.6 N/mm when the thickness of the copper layer is more than 5 μm, wherein a ten-point mean roughness Sz of the roughened surface is lower than that of the base copper layer.

The copper layer may comprise a copper foil.

The copper-clad laminate may further comprise a copper plated layer on one surface of the copper foil.

The ten-point mean roughness Sz of the roughened surface of the copper layer may be below 2.0 μm.

An arithmetic mean roughness Sa of the roughened surface of the copper layer may be below 0.4 μm.

The base copper layer may have a matte side and an opposite shiny side.

The roughening may be conducted on the matte side of the base copper layer.

An arithmetic mean roughness Sa of the roughened matte side of the copper layer may be lower than that of the shiny side of the copper layer.

An arithmetic mean roughness Sa of the roughened matte side of the copper layer is below 0.4 μm.

The copper layer may exhibit an insertion loss of from −3.60 dB to −2.50 dB when measured at a frequency of 5 GHz.

The copper layer may exhibit an insertion loss of from −6.50 dB to −5.00 dB when measured at a frequency of 10 GHz.

The copper layer may exhibit an insertion loss of from −8.50 dB to −6.75 dB when measured at a frequency of 15 GHz.

The copper layer may exhibit an insertion loss of from −11.70 dB to −8.55 dB when measured at a frequency of 20 GHz.

A particle size of roughened particles of the roughened surface of the copper layer may be from 0.1 μm to 2.0 μm.

A height of projections formed of the roughened particles of the roughened surface is from 1.0 μm to 5.0 μm.

The resin layer comprises a thermosetting composition comprising (a) polyphenylene ether or oligomer thereof having at least two unsaturated functional groups which are selected from the group consisting of vinyl group and allyl group at both molecular chain ends; (b) at least three kinds of cross-linkable curing agents; and (c) a flame-retardant.

The polyphenylene ether may be represented by the following Chemical Formula 1:

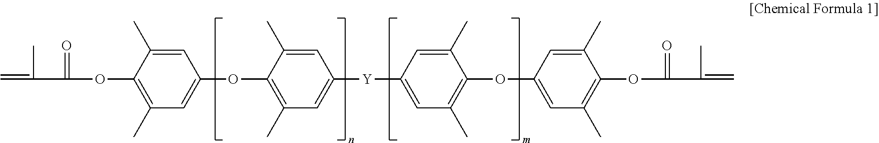

Wherein, in Chemical Formula 1,

Y is at least one compound selected from the group consisting of bisphenol-A based compound, bisphenol-F based compound, bisphenol-S based compound, naphthalene based compound, anthracene based compound, biphenyl based compound, tetramethyl biphenyl based compound, phenol novolac based compound, cresol novolac based compound, bisphenol-A novolac based compound, and bisphenol-S novolac based compound,

m and n are integers independently selected from 3 to 20.

The cross-linkable curing agents may comprise a composition comprising a hydrocarbon based curing agent (b1), a curing agent having at least three functional groups (b2) and a block-structured rubber.

The copper foil may additionally comprise at least one layer selected from the group consisting of a heat-resistant layer, an anti-corrosive layer, a chromate layer and a silane coupling layer on the resin layer.

The copper foil may be an electrodeposited copper foil.

In accordance with one aspect of the present invention, a printed circuit board comprising the copper-clad laminate according to the present invention.

### DESCRIPTION OF SPECIFIC EMBODIMENTS

Hereinafter, preferred embodiments of the present invention will be described. However, the embodiments of the present invention may be modified to various other forms, and the scope of the present invention is not limited to the embodiments described below. In addition, the embodiments of the present invention are provided in order to more completely describe the present invention to those having average knowledge in the art.

After repeated studies, the inventors of the present invention have found out that, in manufacturing a copper-clad laminate, adhesion strength between a copper layer and a resin layer laminated thereon increases and an insertion loss significantly decreases by controlling a thickness and surface roughness of the copper layer to specific ranges, and furthermore, physical properties of significantly superior softness and machinability are secured by controlling the adhesion strength to specific ranges, and have completed the present invention.

One aspect of the present invention relates to a copper-clad laminate including at least one copper layer and a resin layer formed on at least one surface of both surfaces of the copper layer.

[Form of Copper Layer and Preparation Method Thereof]

In the present invention, the copper layer may have a roughened surface, and may be formed by roughening at least one surface of a base copper layer so as to have a low profile.

In addition, a thickness of the copper layer is not particularly limited in the present invention, but may be, for example, from 5 μm to 70 μm, preferably from 5 μm to 50 μm, more preferably from 9 μm to 50 μm, and most preferably from 9 μm to 35 μm.

In the present invention, the base copper layer requisitely includes a copper foil, and may further include a copper plated layer on any one surface of the copper foil.

In the present invention, the copper foil used in the present invention may be an electrolytic copper foil or a rolled copper foil and is not particularly limited, but may preferably be an electrolytic copper foil.

In the present invention, a surface of a side on which an electrodeposited copper foil has been contacted with a cathode drum surface is referred to as “shiny side”, and a reverse surface is referred to as “matte side”.

In the present invention, the electrolytic copper foil has a matte side and a shiny side. In the present invention, by roughening the matte side to be adhered to a resin layer or both surfaces including the matte side of the copper foil, adhesion strength with the resin laminated thereon may be enhanced, and heat resistance and the like may be enhanced in addition thereto.

In the present invention, firstly, the matte side of the copper foil is roughened, and then the copper plated layer may be laminated on any one surface thereof, but the order of the copper plated layer laminating process and the roughening process is not particularly limited.

In the present invention, by carrying out roughening as above, adhesion strength with a resin layer laminated on the copper layer may be enhanced, and an insertion loss and the like may be properly inhibited, and finally, softness and machinability of the copper layer may be enhanced as well.

In the present invention, the roughening process is not particularly limited, and methods known in the art and capable of forming projections on the copper foil surface may be used without limit. However, preferably, a copper foil is introduced to a liquid electrolyte having a temperature comprised between 15 and 30° C. and including copper (Cu) and plating is carried out at specific current density or higher to produce fine nodules (roughened particles) on the copper foil surface.

In addition, the process of capsulating the produced metal nuclei in the present invention may be carried out at a temperature higher than a temperature producing the metal nuclei, and preferably, may be carried out at 45° C. to 60° C., and copper concentration in the liquid electrolyte used may be higher than concentration in the liquid electrolyte producing the metal nuclei.

[Roughened Particles and Projections]

In the present invention, roughened particles are formed on the copper foil surface by such a roughening process, and these may form projections.

In the present invention, diameters of the roughened particles may be from 0.1 μm to 2.0 μm.

In addition, in the present invention, a height of the projection formed by the roughened particles may be from 1.0 μm to 5.0 μm. In the present invention, when the height of the projection is less than 1.0 μm, the height is low and sufficient adhesion strength may not be secured, and when the height of the projection is greater than 5.0 μm, projection distribution is not uniform, and the targeted surface roughness range may be difficult to control.

[Surface Roughness of Copper Layer]

1. Ten-Point Mean Roughness (Sz)

In the present invention, by roughening at least one surface of the base copper layer as above, ten-point mean roughness (Sz) of the roughened surface of the copper layer may be controlled to be lower than ten-point mean roughness (Sz) of the base copper layer that is not roughened.

Specifically, in the present invention, ten-point mean roughness (Sz) of the roughened surface of the copper layer is preferably greater than 0 μm and less than or equal to 2.0 μm, more preferably from 0.1 μm to 1.9 μm, most preferably from 0.15 μm to 1.8 μm.

In the present invention, a method of measuring ten-point mean roughness (Sz) of the copper layer is not particularly limited, but may be in accordance with, for example, the ISO 25178 method.

In the present invention, when the ten-point mean roughness (Sz) is lower than the roughness range limited as above, adhesion strength with a resin significantly decreases, and when the roughness is greater than the roughness range, an insertion loss rapidly increases leading to a significant electrical property decline.

2. Arithmetic Mean Roughness (Sa)

In the present invention, the roughening process can be conducted on any one surface of the base copper layer as above, however, preferably can be conducted on the matte side or both surfaces of the copper layer.

In general, roughening the matte side of the copper foil increases the roughness of the matte side, even the roughness of the matte side becomes greater than that of the shiny side, although the roughness of the matte side is lower than that of the shiny side before roughening.

However, in the present invention, by conducting the roughening process to the matte side of the copper foil under specific conditions, arithmetic mean roughness (Sa) of the matte side is lower than that of the shiny side.

Specifically, arithmetic mean roughness (Sa) of the roughened surface of the copper layer may be greater than 0 μm and less than or equal to 0.4 μm, preferably from 0.1 μm to 0.36 μm, more preferably from 0.14 μm to 0.29 μm and most preferably from 0.15 μm to 0.25 μm.

When a thickness of the copper foil is from 5 μm to 10 μm in the present invention, arithmetic mean roughness (Sa) of the matte side may be from 0.1 μm to 0.4 μm and preferably from 0.15 μm to 0.35 μm. In addition, arithmetic mean roughness (Sa) of the shiny side may be from 0.15 μm to 0.45 μm and preferably from 0.17 μm to 0.40 μm.

When a thickness of the copper foil is greater than 10 μm and less than or equal to 30 μm in the present invention, arithmetic mean roughness (Sa) of the matte side may be from 0.15 μm to 0.35 μm and preferably from 0.16 μm to 0.30 μm. In addition, arithmetic mean roughness (Sa) of the shiny side may be from 0.20 μm to 0.40 μm and preferably from 0.20 μm to 0.35 μm.

When a thickness of the copper foil is greater than 30 μm and less than or equal to 70 μm in the present invention, arithmetic mean roughness (Sa) of the matte side may be from 0.05 μm to 0.33 μm and preferably from 0.08 μm to 0.29 μm. In addition, arithmetic mean roughness (Sa) of the shiny side may be from 0.15 μm to 0.35 μm and preferably from 0.18 μm to 0.30 μm.

In the present invention, a method of measuring arithmetic mean roughness (Sa) of the roughened surface of the copper layer is not particularly limited, but may be in accordance with, for example, the ISO 25178 method.

In the present invention, when the arithmetic mean roughness (Sa) is lower than the roughness range limited as above, adhesion strength with a resin significantly decreases, and when the roughness is greater than the roughness range, an insertion loss rapidly increases leading to a significant electrical property decline.

In the present invention, by controlling a thickness of the copper layer and roughness of the roughened surface of the electrolytic copper foil included in the copper layer to specific ranges, adhesion strength with a resin is enhanced, a low insertion loss may be secured as well.

[Adhesion Strength between Copper Layer and Resin Layer]

In the present invention, physical properties of softness and machinability may be significantly enhanced by controlling adhesion strength between the copper layer and the resin layer to specific ranges.

When a thickness of the copper layer is from 5 μm to 70 μm in the present invention, adhesion strength between the copper layer and the resin layer laminated thereon may be 0.6 N/mm or greater, preferably from 0.6 N/mm to 1.0 N/mm and more preferably from 0.6 N/mm to 0.9 N/mm. When adhesion strength between the copper layer and the resin layer is less than 0.6 N/mm in the present invention, the copper layer and the resin layer are readily detached, and in this case, deformation behavior of the resin layer may not be transferred to the copper layer leading to a decrease in the softness of the copper layer, and machinability by press forming and the like may significantly decrease as well later on.

In the present invention, a method of measuring the adhesion strength is not particularly limited, however, the adhesive strength may be measured in accordance with IPC-TM-650 using a peel strength tensile tester INSTRON™ 5543.

[Insertion Loss of Copper-Clad Laminate]

When an insertion loss is small, signal attenuation is suppressed when transmitting signals at a high frequency, and therefore, stable signal transmission may be obtained in a circuit transmitting signals at a high frequency. Accordingly, having a smaller insertion loss value is preferred since it is suitable to be used in circuit applications transmitting signals at a high frequency.

The copper-clad laminate of the present invention preferably has an insertion loss of from −3.60 dB to −2.50 dB, more preferably from −3.35 dB to −2.75 dB and even more preferably from −3.25 dB to −3.05 dB when measured at a frequency of 5 GHz.

The copper-clad laminate of the present invention preferably has an insertion loss of from −6.50 dB to −5.00 dB, more preferably from −6.25 dB to −5.15 dB and even more preferably from −6.15 dB to −5.20 dB when measured at a frequency of 10 GHz.

The copper-clad laminate of the present invention preferably has an insertion loss of from −8.50 dB to −6.75 dB, more preferably from −8.25 dB to −7.10 dB and even more preferably from −7.90 dB to −7.15 dB when measured at a frequency of 15 GHz.

The copper-clad laminate of the present invention preferably has an insertion loss of from −11.70 dB to −8.55 dB, more preferably from −11.25 dB to −9.15 dB and even more preferably from −10.50 dB to −9.25 dB when measured at a frequency of 20 GHz.

In the present invention, the insertion loss means, when applying electric signals of a specific frequency to the copper-clad laminate according to the present invention, a ratio of an output voltage with respect to the input voltage, and specifically, may be measured using the following equation.

Insertion loss (dB)=−20 log₁₀|S₂₁|

Herein, ‘S₂₁’ means penetrated wave voltage/incident wave voltage.

As is apparent from examples and comparative examples to be described below, the surface treated copper foil of the present invention having both surface roughness and insertion loss as above may have excellent adhesion with a resin laminated thereon and may have a property of low insertion loss.

[Composition of the Resin Layer]

In the present invention, the resin layer may be laminated on at least one surface of the copper layer.

In the present invention, the resin layer may include a non-epoxy-based thermosetting resin composition, and the non-epoxy-based thermosetting resin composition provided in the present invention has properties of overall physical properties including heat resistance and low dielectric properties being excellent by using both a polyphenylene ether resin in which both sides of the molecular chain are modified with unsaturated bond substituents and three or more types of specific cross-linkable curing agents.

The non-epoxy-based thermosetting resin composition in the present invention includes (a) polyphenylene ether having two or more unsaturated substituents selected from the group consisting of vinyl groups and allyl groups on both ends of a molecular chain, or an oligomer thereof; (b) three or more types of cross-linkable curing agents; and (c) a flame retardant. In addition, the thermosetting resin composition may further include an inorganic filler of which surface is treated with a vinyl group-containing silane coupling agent. Herein, a curing accelerator, an initiator (for example, a radical initiator) and the like may be further included as necessary.

(a) Polyphenylene Ether

The thermosetting resin composition according to the present invention includes polyphenylene ether (PPE) or an oligomer thereof. The PPE or the oligomer thereof has two or more vinyl groups, allyl groups or both thereof on both ends of the molecular chain, however, the structure is not particular limited.

In the present invention, allylated polyphenylene ether represented by the following Chemical Formula 1 is preferred: this is due to the fact sides of the compound are modified with two or more vinyl groups, and therefore, the compound is capable of enhancing a glass transition temperature, and satisfying a low coefficient of thermal expansion, a moisture resistance property caused by a decrease in the —OH group, and a dielectric property.

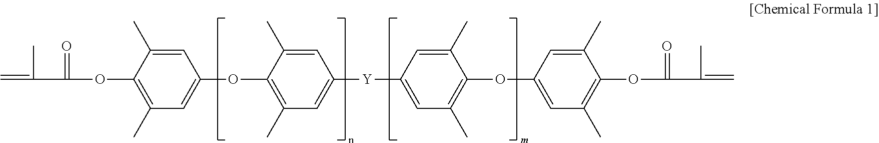

In Chemical Formula 1, Y is one or more types of compounds selected from the group consisting of a bisphenol A-type, a bisphenol F-type, a bisphenol S-type, a naphthalene-type, an anthracene-type, a biphenyl-type, a tetramethyl biphenyl-type, a phenol novolac-type, a cresol novolac-type, a bisphenol A novolac-type and a bisphenol S novolac-type, and m and n are each independently a natural number of 3 to 20.

In the present invention, those having 2 or more vinyl groups on both ends of the molecular chain are normally used, however, those using common unsaturated double bond moieties known in the art besides the vinyl group also belong to the scope of the present invention.

Meanwhile, polyphenylene ether intrinsically has a high melting point and viscosity of the melt of the resin composition is high, and therefore, producing a multilayer sheet is difficult. Accordingly, in the present invention, using a form modified to a low molecular weight through a redistribution reaction is preferred instead of using existing high molecular weight polyphenylene ether as it is.

Particularly, phenol-derived compounds or compounds such as bisphenol A are generally used when modifying existing high molecular weight polyphenylene ether to a low molecular weight polyphenylene ether resin, and in this case, a phenomenon of dielectric constant decrease occurs since rotation in the molecular structure possibly occurs.

Meanwhile, in the present invention, instead using an existing high molecular weight polyphenylene ether (PPE) resin as it is, a form of introducing vinyl groups on both ends of the resin through redistribution is used as a form modified to a low molecular weight through a redistribution reaction using specific bisphenol compounds having increased alkyl group content and aromatic group content. Herein, the redistribution reaction is carried out under the presence of a radical initiator, a catalyst, or both a radical initiator and a catalyst.

Specifically, existing polyphenylene ether for a copper-clad laminate has been used after modifying high molecular polyphenylene ether to low molecular polyphenylene ether having alcohol groups on both ends through a redistribution reaction using polyphenol and a radical initiator as a catalyst, however, there has been a limit in obtaining a low dielectric loss property due to structural properties of Bisphenol A, a polyphenol used in existing redistribution, and high polarity of alcohol groups on both ends produced after redistribution.

In comparison, polyphenylene ether having small dielectric loss even after cross-linkage may be obtained in the present invention by redistributing polyphenol used in a redistribution reaction using specific bisphenol compounds having increased alkyl group content and aromatic group content, and then modifying alcohol groups present on both ends to vinyl groups with low polarity. Such modified polyphenylene ether has a lower molecular weight compared to existing polyphenylene-derived compounds and has high alkyl group content, and therefore, has excellent compatibility with existing epoxy resins and the like, and processibility is improved since flowability increases when manufacturing a laminate, and a dielectric property is additionally improved. Accordingly, a printed circuit board manufactured using the resin composition of the present invention has an advantage of enhancing physical properties such as moldability, machinability, a dielectric property, heat resistance and adhesion strength.

Herein, as the specific bisphenol compound having increased alkyl group content and aromatic group content, bisphenol series compounds except Bisphenol A [BPA, 2,2-bis(4-hydroxyphenyl)propane] may be used without limit. Nonlimiting examples of the usable bisphenol compound may include Bisphenol AP (1,1-bis(4-hydroxyphenyl)−1-phenyl-ethane), Bisphenol AF (2,2-bis(4-hydroxyphenyl)hexafluoropropane), Bisphenol B (2,2-bis(4-hydroxyphenyl)butane), Bisphenol BP (bis-(4-hydroxyphenyl)diphenylmethane), Bisphenol C (2,2-bis(3-methyl-4-hydroxyphenyl)propane), Bisphenol C (bis(4-hydroxyphenyl)−2,2-dichloroethylene), Bisphenol G (2,2-bis(4-hydroxy-3-isopropyl-phenyl)propane), Bisphenol M (1,3-bis(2-(4-hydroxyphenyl)−2-propyl)benzene), Bisphenol P (bis(4-hydroxyphenyl)sulfone), Bisphenol PH (5,5′-(1-methylethyliden)-bis [1,1′-(bisphenyl)−2-ol] propane), Bisphenol TMC (1,1-bis(4-hydroxyphenyl)−3,3,5-trimethyl-cyclohexane), Bisphenol Z (1,1-bis(4-hydroxyphenyl)-cyclohexane), a mixture of one or more types thereof, or the like.

The polyphenylene ether resin (a) may be obtained by modifying a high molecular weight polyphenylene ether resin having a number average molecular weight range of 10,000 to 30,000 to a low molecular weight having a number average molecular weight (Mn) range of 1,000 to 10,000 through a redistribution reaction under the presence of a bisphenol series compound (except Bisphenol A), and the number average molecular weight (Mn) may be preferably in a 1000 to 5,000 range, and more preferably in a 1000 to 3000 range.

In addition, molecular weight distribution of the polyphenylene ether is suitably 3 or less (Mw/Mn<3), and preferably in a range of 1.5 to 2.5.

In the thermosetting resin composition according to the present invention, the content of the polyphenylene ether resin or the oligomer thereof may be approximately from 20% by weight to 50% by weight based on the total weight of the resin composition.

(b) Cross-Linkable Curing Agent

The thermosetting resin composition according to the present invention includes three or more types of different cross-linkable curing agents.

The cross-linkable curing agent forms a network structure by three-dimensionally cross-linking the polyphenylene ether, and even when polyphenylene ether modified to a low molecular weight is used for increasing flowability of the resin composition, heat resistance of the polyphenylene ether may be improved due to the use of the three or more types of cross-linkable curing agents. In addition, by cross-linking PPE, the cross-linkable curing agent may increase flowability of the cured resin composition and enhance peel strength with other base materials (for example, copper foil) while obtaining low dielectric constant and dielectric loss property.

The cross-linkable curing agent may be selected from the group consisting of a hydrocarbon-based cross-linking agent (b1), a cross-linking agent containing three or more functional groups (b2) and block-structured rubber (b3).

According to one example, a hydrocarbon-based cross-linking agent (b1), a cross-linking agent containing three or more functional groups (b2) and block-structured rubber (b3) may be mixed and used as the cross-linkable curing agent.

In the present invention, the usable hydrocarbon-based cross-linking agent is not particularly limited as long as it is a hydrocarbon-based cross-linking agent having double bonds or triple bonds, and preferably, may be a diene-based cross-linking agent. Specific examples thereof may include butadiene (for example, 1,2-butadiene, 1,3-butadiene and the like) or polymers thereof, decadiene (for example, 1,9-decadiene and the like) or polymers thereof, octadiene (for example, 1,7-octadiene and the like) or polymers thereof, vinyl carbazole, and the like, and these may be used either alone or as a mixture of two or more types.

According to one example, polybutadiene represented by the following Chemical Formula 2 may be used as the hydrocarbon-based cross-linking agent:

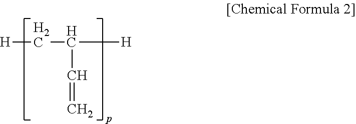

(In Chemical Formula 2, p is an integer of 10 to 30.)

The hydrocarbon-based cross-linking agent may have a molecular weight (Mw) range of 500 to 3,000, and preferably, may have a range of 1,000 to 3,000.

In the present invention, nonlimiting examples of the usable cross-linking agent containing three or more (preferably 3 to 4) functional groups may include triallyl isocyanurate (TAIL), 1,2,4-trivinyl cyclohexane (TVCH) and the like, and these may be used either alone or as a mixture of two or more types.

According to one example, triallyl isocyanurate (TAIL) represented by the following Chemical Formula 3 may be used as the cross-linking agent containing three or more functional groups:

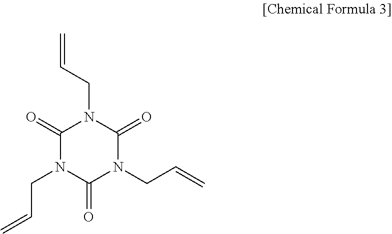 [SMILES: C=CCn1c(=O)n(CC=C)c(=O)n(CC=C)c1=O]

In the present invention, the usable block-structured rubber has a block copolymer form, and may preferably be block copolymer-type rubber containing a butadiene unit, and more preferably, block copolymer-type rubber containing units such as a styrene unit, an acrylonitrile unit and an acrylate unit together with the butadiene unit. Nonlimiting examples thereof may include styrene-butadiene rubber (SBR), acrylonitrile-butadiene rubber, acrylate-butadiene rubber, acrylonitrile-butadiene-styrene rubber and the like, and these may be used either alone or as a mixture of two or more types.

According to one example, styrene-butadiene rubber represented by the following Chemical Formula 4 may be used as the block-structured rubber:

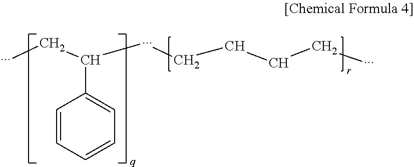

(In Chemical Formula 4, q is an integer of 5 to 20 and r is an integer of 5 to 20.)

In the present invention, the content of the cross-linkable curing agent (b) in the thermosetting resin composition is not particularly limited, but may be in a range of approximately 5% by weight to 45% by weight based on the total weight of the resin composition, and preferably, may be in a range of approximately 10% by weight to 30% by weight. When the content of the cross-linkable curing agent is within the range described above, a low dielectric property, curability, molding machinability and adhesion strength of the resin composition are favorable.

According to one example, when mixing the hydrocarbon-based cross-linking agent (b1), the cross-linking agent containing three or more functional groups (b2) and the block-structured rubber as the three or more types of cross-linkable curing agents, each content of the hydrocarbon-based cross-linking agent (b1), the cross-linking agent containing three or more functional groups (b2) and the block-structured rubber (b3) is in an approximately 1.65% by weight to 15% by weight range, preferably in an approximately 3.33% by weight to 10% by weight range, and more preferably in an approximately 5% by weight to 10% by weight range, based on the total weight of the resin composition.

According to another example, when mixing the hydrocarbon-based cross-linking agent (b1), the cross-linking agent containing three or more functional groups (b2) and the block-structured rubber as the three or more types of cross-linkable curing agents, the ratio of the hydrocarbon-based cross-linking agent (b1), the cross-linking agent containing three or more functional groups (b2) and the block-structured rubber (b3) used is a weight ratio of b1:b2:b3=1 to 20:1 to 20:1, and preferably a weight ratio of b1:b2:b3=1 to 7:1 to 7:1.

As necessary, in the present invention, common cross-linkable curing agents known in the art may be further included in addition to the hydrocarbon-based curing agent, the cross-linking agent containing three or more functional groups and the block-structured rubber described above. Herein, the cross-linkable curing agent preferably has excellent miscibility with polyphenylene ether of which sides are modified with vinyl groups, allyl groups and the like.

Nonlimiting examples of the usable cross-linkable curing agent may include divinyl naphthalene, divinyldiphenyl, styrene monomers, phenol, triallyl cyanurate (TAC), di-(4-vinylbenzyl) ether (following Chemical Formula 5) and the like. Herein, the curing agent described above may be used either alone or as a mixture of two or more types.

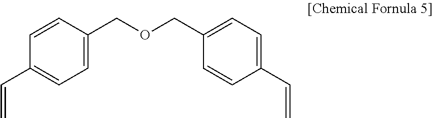 [SMILES: C=Cc1ccc(COCc2ccc(C=C)cc2)cc1]

In the present invention, various physical properties and machinability as well as a low dielectric property may be maximized through proper mixing and optimized content control of the cross-linkable curing agent described above. Particularly, by mixing di-(4-vinylbenzyl) ether (Chemical Formula 5) exhibiting an initiation delay reaction effect as the cross-linking agent with other cross-linkable curing agents (hydrocarbon-based curing agent, curing agent containing three or more functional groups and block-structured rubber) in optimized content in the present invention, viscosity may be readily controlled. By controlling resin flowability based thereon, difficulties in prepreg handling or molding machinability may be overcome.

Specifically, when mixing di-4-vinylbenzyl ether with the hydrocarbon-based curing agent, the curing agent containing three or more functional groups and the block-structured rubber as the cross-linkable curing agent, both a low dielectric property and a flow property caused by content control may be secured. Herein, the hydrocarbon-based curing agent, the curing agent containing three or more functional groups and the block-structured rubber may be each used in an approximately 1.65% by weight to 15% by weight range, preferably used in an approximately 3.33% by weight to 10% by weight range and more preferably used in an approximately 5% by weight to 10% by weight range, based on the total weight of the resin composition, and the di-4-vinylbenzyl ether may be used in an approximately 1% by weight to 10% by weight range and preferably in an approximately 2% by weight to 5% by weight range with respect to the total weight of the resin composition.

(c) Flame Retardant

In the present invention, the thermosetting resin composition may include a flame retardant (c).

As the flame retardant, common flame retardants known in the art may be used without limit, and as one example, halogen flame retardants containing bromine or chlorine; phosphorous flame retardants such as triphenyl phosphate, tricresyl phosphate, trisdichloropropylphosphate and phosphazene; antimony-based flame retardants such as antimony trioxide; inorganic flame retardants such as metal hydroxides such as aluminum hydroxide and magnesium hydroxide may be included. In the present invention, an addition-type bromine flame retardant that is not reactive with polyphenylene ether and does not decline a heat resisting property and a dielectric property is suitable.

In the present invention, the brominated flame retardant may obtain both curing agent properties and flame resisting properties by using bromophthalimide or a bromophenyl addition-type bromine flame retardant, or allyl terminated-type tetrabromo Bisphenol A (tetrabromo bisphenol A allyl ether) or a divinylphenol-type flame resistant curing agent. In addition, brominated organic compounds may also be used, and specific examples thereof may include decabromodiphenylethane, 4,4-dibromobiphenyl, ethylenebistetrabromophthalimide and the like.

In the thermosetting resin composition of the present invention, the flame retardant may be included in approximately 10% by weight to 30% by weight based on the total weight of the resin composition, and preferably, may be included in an approximately 10% by weight to 20% by weight range. When the flame retardant is included in the above-mentioned range, sufficient flame resistance of a flame resistance 94V-0 level may be obtained, and excellent heat resistance and electrical properties may be obtained.

(d) Inorganic Filler of Which Surface is Treated with Vinyl Group-Containing Silane Coupling Agent

The thermosetting resin composition according to the present invention may further include an inorganic filler of which surface is treated with a vinyl group-containing silane coupling agent.

The inorganic filler has a surface treated with a vinyl group-containing silane coupling agent, and this is capable of further enhancing moisture absorbing heat resistance and machinability while lowering a dielectric property due to excellent compatibility with polyphenylene ether containing vinyl groups and/or allyl groups on both ends. In addition, the inorganic filler reduces a difference in the coefficient of thermal expansion (CTE) between the resin layer and other layers, and is capable of effectively enhancing a bending property, low expansion, mechanical strength (toughness) and low stress of final products.

In the present invention, the usable inorganic filler (d) is not particularly limited as long as it is an inorganic filler known in the art and its surface is treated with a vinyl group-containing silane coupling agent. Examples thereof may include silicas such as natural silica, fused silica, amorphous silica and crystalline silica; boehmite, alumina, talc, spherical glass, calcium carbonate, magnesium carbonate, magnesia, clay, calcium silicate, titanium oxide, antimony oxide, glass fiber, aluminum borate, barium titanate, strontium titanate, calcium titanate, magnesium titanate, bismuth titanate, titanium oxide, barium zirconate, calcium zirconate, boron nitride, silicon nitride, mica and the like, and surfaces thereof are treated with a vinyl group-containing silane coupling agent. Such an inorganic filler may be used either alone or as a mixture of two or more. Among these, fused silica exhibiting a low coefficient of thermal expansion is preferred.

A method for preparing the inorganic filler of which surface is treated with a vinyl group-containing silane coupling agent is not particularly limited, and common methods known in the art may be used. As one example, the inorganic filler of which surface is treated with a vinyl group-containing silane coupling agent may be prepared by introducing an inorganic filler to a solution including a vinyl group-containing silane coupling agent and then drying the result.

The size of the inorganic filler (d) is not particularly limited, however, having a mean particle diameter of approximately 0.5 μm to 5 μm range is advantageous in terms of dispersibility.

In addition, the content of the inorganic filler is not particularly limited, and may be properly controlled considering a bending property, mechanical properties and the like described above. As one example, a range of approximately 10% by weight to 50% by weight based on the total weight of the thermosetting resin composition is preferred. When the inorganic filler is excessively included, moldability may decline.

Meanwhile, the thermosetting resin composition according to the present invention may further include a reaction initiator for strengthening advantageous effects of the cross-linkable curing agent.

Such a reaction initiator may further accelerate curing of the polyphenylene ether and the cross-linkable curing agent, and may improve properties such as heat resistance of the resin.

Nonlimiting examples of the usable initiator may include α,α′-bis(t-butylperoxy-m-isopropyl)benzene, 2,5-dimethyl-2,5-di(t-butylperoxy)−3-hexyne, benzoyl peroxide, 3,3′,5,5′-tetramethyl-1,4-diphenoxyquinone, chloranyl, 2,4,6-tri-t-butylphenoxyl, t-butylperoxyisopropyl monocarbonate, azobisisobutylonitrile and the like, and metal carboxylate salts may be further used additionally.

The content of the reaction initiator may be from approximately 2 parts by weight to 5 parts by weight with respect to 100 parts by weight of the polyphenylene ether, but is not limited thereto.

In addition, the thermosetting resin composition of the present invention may further include a curing accelerator.

Examples of the curing accelerator may include organic metal salts or organic metal complexes including one or more metals selected from the group consisting of iron, copper, zinc, cobalt, lead, nickel, manganese and tin.

Specific examples of the organic metal salt or organic metal complex may include iron napthenate, copper napthenate, zinc napthenate, cobalt napthenate, nickel napthenate, manganese napthenate, tin napthenate, zinc octanoate, tin octanoate, iron octanoate, copper octanoate, zinc 2-ethyl hexanate, lead acetylacetonate, cobalt acetylacetonate, dibutyltin maleate and the like, but are not limited thereto. In addition, these may be used as either one type, or as a mixture of two or more types.

The content of the curing accelerator may be in a range of approximately 0.01 parts by weight to 1 parts by weight with respect to 10 parts by weight to 60 parts by weight of the polyphenylene ether, but is not limited thereto.

In addition to the components described above, the thermosetting resin composition of the present invention may additionally include, as long as it does not harm unique properties of the resin composition, a flame retardant generally known in the art, various polymers such as other thermosetting resins that are not described above or thermoplastic resins and oligomers thereof, solid rubber particles, or other additives such as an ultraviolet absorber, an antioxidant, a polymerization initiator, a dye, a pigment, a dispersant, a viscosity agent and a leveling agent as necessary. As one example, an organic filler such as silicone-based powder, nylon powder and fluorine resin powder, a viscosity agent such as Orbene and bentone; a polymer-based antifoamer or leveling agent such as a silicone-based and a fluorine resin-based; a tackifier such as an imidazole-based, a thiazole-based, a triazole-based and a silane-based coupling agent; a colorant such as phthalocyanine and carbon black, and the like, may be included.

With a purpose of providing proper flexibility and the like to the resin composition after curing, a thermoplastic resin may be mixed to the thermosetting resin composition. Examples of such a thermoplastic resin may include a phenoxy resin, a polyvinyl acetal resin, polyimide, polyamide-imide, polyethersulfone, polysulfone and the like. These may be favorably used as just any one type, or as a combination of two or more types.

As the resin additives, an organic filler such as silicone powder, nylon powder and fluorine resin powder, a viscosity agent such as Orbene and bentone; a silicone-based, a fluorine-based and a polymer-based antifoamer or leveling agent; a tackifier such as an imidazole-based, a thiazole-based, a triazole-based, a silane coupling agent, epoxysilane, aminosilane, alkylsilane and mercaptosilane; a colorant such as phthalocyanine blue, phthalocyanine green, iodine green, disazo yellow and carbon black; a releasing agent such as higher fatty acid, higher fatty acid metal salts and ester-based wax; a stress releasing agent such as modified silicone oil, silicone powder and a silicone resin, and the like, may be included. In addition, additives commonly used in thermosetting resin compositions used for producing electronic devices (particularly, printed wiring boards) may be included.

According to one example of the present invention, the thermosetting resin composition may include, based on 100 parts by weight of the composition, (a) the polyphenylene ether resin having two or more unsaturated substituents on both ends of the molecular chain in approximately 20 parts by weight to 50 parts by weight; (b) the three or more types of cross-linkable curing agents in approximately 5 parts by weight to 45 parts by weight; and (c) the flame retardant in approximately 10 parts by weight to 30 parts by weight range, and may further include an organic solvent or other components to satisfy a total of 100 parts by weight. Herein, the components may be based on the total weight of the composition, or the total weight of the varnish including the organic solvent.

According to another example of the present invention, the thermosetting resin composition may include, based on 100 parts by weight of the composition, (a) the polyphenylene ether resin having two or more unsaturated substituents on both ends of the molecular chain in approximately 20 parts by weight to 50 parts by weight; (b) the three or more types of cross-linkable curing agents in approximately 5 parts by weight to 45 parts by weight; (c) the flame retardant in approximately 10 parts by weight to 30 parts by weight; and (d) the inorganic filler of which surface is treated with a vinyl group-containing silane coupling agent in approximately 10 parts by weight to 50 parts by weight range, and may further include an organic solvent or other components to satisfy a total of 100 parts by weight. Herein, the components may be based on the total weight of the composition, or the total weight of the varnish including the organic solvent.

In the present invention, common organic solvents known in the art may be used as the usable organic solvent without limit, and one example thereof may include acetone, cyclohexanone, methyl ethyl ketone, toluene, xylene, tetrahydrofuran and the like, and these may be used either alone or as a mixture of two or more types.

The content of the organic solvent may be in a residual quantity satisfying the total of 100 parts by weight of the varnish using the composition ratio of the compositions described above, and is not particularly limited.

In the present invention, in order to increase chemical adhesion strength between the copper foil and such a resin layer, any one surface of the copper foil on which the resin layer is to be laminated may be treated with a silane coupling agent.

In the present invention, as the silane coupling agent, materials known in the art may be used without particular limit, and nonlimiting examples thereof may include 3-aminopropyltriethoxysilane, 3-aminopropyltrimethoxysilane, N-2-(aminoethyl)−3-aminopropyltriethoxysilane, N-2-(aminoethyl)−3-aminopropylmethyldimethoxysilane, N-2-(aminoethyl)−3-aminopropyltrimethoxysilane, N-phenyl-3-aminopropyltrimethoxysilane, N-(vinylbenzyl)−2-aminoethyl-3-aminopropyl trimethoxysilane, 3-(N-styrylmethyl-2-aminoethylamino)propyl trimethoxysilane, bis(2-hydroxyethyl)−3-aminopropyl triethoxysilane, N-methylaminopropyl trimethoxysilane, N-(3-acryloxy-2-hydroxypropyl)−3-aminopropyl triethoxysilane, 4-aminobutyl triethoxysilane, (aminoethyl aminomethyl)phenetyl trimethoxysilane, N-(2-aminoethyl-3-aminopropyl)tris(2-ethylhexoxy) silane, 6-(aminohexyl aminopropyl)trimethoxysilane, aminophenyl trimethoxysilane, 3-(1-aminopropoxy)−3,3-dimethyl-1-prophenyl trimethoxysilane, 3-aminopropyltris(methoxyethoxyethoxy)silane, ω-aminoundecyltrimethoxysilane, 3-(2-N-benzylaminoethyl aminopropyl)trimethoxysilane, bis(2-hydroxyethyl)−3-aminopropyltriethoxysilane, 3-glycidoxypropyltriethoxysilane, 3-glycidoxypropylmethyldiethoxysilane, 3-tricidoxypropyltrimethoxysilane, 3-glycidoxypropylmethyldimethoxysilane, 2-(3,4-epoxycyclohexyl)ethyltrimethoxysilane, vinyltriacetoxysilane, vinyltriethoxysilane, vinyltrimethoxysilane, vinyltriisopropoxysilane, vinyltrichlorosilane, allyltrimethoxysilane, diallyldimethylsilane, 3-methacryloxypropyltriethoxysilane, 3-methacryloxypropylmethyldiethoxysilane, 3-methacryloxypropyltrimethoxysilane, 3-methacryloxypropylmethyldimethoxysilane, 3-acryloxypropyltrimethoxysilane, 3-mercaptopropyltrimethoxysilane, 3-mercaptopropyltriethoxysilane, 3-mercaptopropylmethyldimethoxysilane, 3-mercaptopropyltrimethoxysilane, N-(1,3-dimethylbutylidene)−3-aminopropyltriethoxysilane, p-styryltrimethoxysilane, 3-ureide propyltriethoxysilane, 3-chloropropyltrimethoxysilane, 3-isocyanate propyltriethoxysilane and the like, and preferably, 3-aminopropyltriethoxysilane may be used.

In the present invention, the method of treating one surface of the copper layer with a silane coupling agent is not particularly limited, and a process of spraying a silane coupling agent having a concentration of 0.1 g/l to 10 g/l to the copper layer (or depositing the copper layer in a silane coupling agent for 0.5 seconds to 5 seconds) at room temperature (specifically 20° C. to 30° C.), and then drying the result at 100° C. to 250° C. may be used.

In the present invention, when treating a surface of the copper layer through such a process, it is preferable to carry out flushing between a prior process and a posterior process so that the liquid electrolyte of the prior process and the posterior process are not mixed.

[Structure of the Copper Clad Laminate]

In the present invention, the structure of the copper-clad laminate is not particularly limited, and the copper-clad laminate is formed in various structures having a form binding the copper foil and the resin layer as a base.

[Printed Circuit Board and Electronic Device]

Still another embodiment of the present invention relates to a printed circuit board including the copper-clad laminate according to the present invention.

In the present invention, the printed circuit board refers to a printed circuit board laminating one or more layers using a plating through a hole method or a build-up method, and may be obtained by stacking and adjusting the above-described prepreg or insulating resin sheet on an inner layer wiring board, and heating and pressing the result.

The printed circuit board may be manufactured using common methods known in the art. As one preferred example thereof, the printed circuit board may be manufactured by laminating a copper foil on one surface or both surfaces of the prepreg according to the present invention, heating and pressing the result to prepare a copper layer laminate, and then carrying out a through hole plating by opening a hole on the copper layer laminate, and forming a circuit through etching the copper foil including the plated film.

Yet another embodiment of the present invention relates to an electronic device including the printed circuit board according to the present invention.

Hereinafter, the present invention will be described in more detail with reference to examples. However, the following examples are just preferred examples of the present invention, and the present invention is not limited to the following examples.

### EXAMPLE

### [Example] Manufacture of Copper-Clad Laminate

An electrolytic copper foil was prepared using a drum made of titanium having surface roughness Ra of 0.25 μm or less, and through electrolytic deposition, the total thickness was made to 9 μm, 12 μm, 18 μm and 35 μm. After that, a liquid electrolyte having a composition of the following Table 1 was prepared, and roughening was carried out to the matte side of the copper foil. When the thickness of the electrolytic copper foil was less than 35 μm, a copper layer having the same composition was plated on a shiny side of the copper foil to make the total thickness 35 μm. A thermosetting resin composition having a composition of the following Table 2 was coated on a matte side of the copper foil, and then the result was dried for approximately 3 minutes to 10 minutes at 165° C.

TABLE 1
Liquid Electrolyte Composition

| Copper | Acid | Current Density | Temperature |
|---|---|---|---|
| 20 g/L | 60 g/L | 30 A/dm² | 20° C. |

TABLE 2

| Composition | Parts by Weight |
|---|---|
| Allylate PPE | 40 |
| TAIC | 8 |
| 1,2-Butadiene | 8 |
| Di-(4-vinylbenzyl)ether | 2 |
| SBR | 3 |
| Flame Retardant | 9 |
| Initiator | 2 |
| Inorganic filler of Which Surface | 30 |
| is Treated with Vinyl Silane | |
| Vinyl Silane G/F | ◯ |

Note
1) Allylate PPE: MX-9000 (number average molecular weight: 2000 to 3000)
2) 1,2-butadiene: B-1000 (NIPPON SODA)
3) Styrene-butadiene: P-1500 (Asahi Kasei Chemical)
4) TAIC: TAIC (NIPPON KASEI CHEMICAL)
5) Di-(4-vinylbenzyl)ether: BPA-DAE (HAOHUA INDUSTRY)
6) Flame retardant: Saytex 8010 (Albemarle Asano Corporation)
7) Initiator: Perbutyl P (manufactured by NOF Corporation)
8) Inorganic filler: SC-5200SQ (manufactured by Admatechs)

### Test Example 1

1. Measurement of Ten-Point Mean Roughness

Ten-point mean roughness was measured for the matte side of the electrolytic copper foil exposed to the outside of the copper layer obtained in the example. The ten-point mean roughness was measured in accordance with ISO 25178.

2. Measurement of Arithmetic Mean Roughness

For the electrolytic copper foil, arithmetic mean roughness was measured for the matte side and the shiny side of the copper foil after roughening the matte side and prior to forming a copper plated layer on the copper foil. The arithmetic mean roughness was also measured in accordance with ISO 25178.

3. Measurement of Adhesion Strength

Normal peel strength was measured in accordance with IPC-TM-650 using a peel strength tensile tester Instron 5543.

4. Measurement of Insertion Loss

An insertion loss for the copper layer was measured using a BD-622 insertion loss and return loss tester manufactured by B&D Technology Co., Ltd.

(Shanghai, China) prior to forming the thermoplastic resin layer.

5. Measurement of Tensile Strength

A plurality of narrow-shaped tensile strength test pieces having a width of 12.7 mm were prepared from the copper-clad laminate. After that, tensile strength was measured under a temperature of 25° C. in accordance with JIS-Z 2241 using a tensile tester.

6. Measurement of Machinability

Machinability was evaluated using a cup test apparatus. The cup test apparatus is equipped with a pedestal and a punch, and the pedestal has a truncated cone-shaped inclined surface, and with the end of the truncated cone becoming thinner from top to bottom, the inclined surface of the truncated cone forms a 60° angle from the horizontal surface. In addition, the bottom of the truncated cone is communicated with a circular hole having a diameter of 15 mm and a depth of 7 mm. Meanwhile, the punch forms a hemispheric column of which tip has a diameter of 14 mm, and the hemispheric unit of the punch tip may be inserted to the circular hole of the truncated cone.

In addition, the tip of the truncated cone having a thinner end and the connecting part of the circular hole at the bottom of the truncated cone is rounded with a radius of (r)=3 mm.

The copper-clad laminate was punched out to the test piece in a circular plate shape with a diameter of 30 mm, and a copper foil composite was disposed on the inclined surface of the truncated cone of the pedestal, and the punch was pushed down from the top of the test piece to be inserted into the circular hole of the pedestal. As a result, the test piece was formed in a conical cup shape.

In addition, when the resin layer was only on one surface of the copper-clad laminate, the resin layer was faced upward when disposed on the pedestal. When the resin layer was on both surfaces of the copper-clad laminate, the resin layer adhering to the M surface was faced upward when disposed on the pedestal. When both surfaces of the copper-clad laminate were Cu, either face may be faced upward.

Cracks on the copper foil in the test piece after forming were visually determined, and machinability was evaluated using the following criteria.

⊚: The copper foil was not cracked, and had no wrinkles.
∘: The copper foil was not cracked but had some wrinkles.
x: The copper foil was cracked.

Results of measuring surface roughness for each of the copper foils as above are as shown in the following Table 3. Results of measuring adhesion strength, insertion loss, tensile strength and machinability for each of the copper foils as above are as shown in the following Table 4.

TABLE 3

| | Copper layer | | | | | |
|---|---|---|---|---|---|---|
| | | Treated copper layer | | | | Copper clad |
| | | | Sa of | Sa of | Untreated | laminate |
| | | | Matte | Shiny | copper | Adhesion |
| | Thickness | Sz | Side | Side | layer | Strength |
| Category | (μm) | (μm) | (μm) | (μm) | Sz(μm) | (N/mm) |
| Comparative | 9 | 1.21 | 0.13 | 0.20 | 1.30 | 0.58 |
| Example 1 | | | | | | |
| Comparative | | 1.18 | 0.17 | 0.25 | 1.35 | 0.55 |
| Example 2 | | | | | | |
| Example 1 | | 1.41 | 0.21 | 0.24 | 1.55 | 0.79 |
| Example 2 | | 1.57 | 0.23 | 0.38 | 1.75 | 0.84 |
| Example 3 | | 1.65 | 0.26 | 0.28 | 1.72 | 0.81 |
| Example 4 | | 1.85 | 0.45 | 0.49 | 1.98 | 0.81 |
| Comparative | 12 | 1.23 | 0.12 | 0.18 | 1.31 | 0.54 |
| Example 3 | | | | | | |
| Comparative | | 1.15 | 0.16 | 0.25 | 1.24 | 0.49 |
| Example 4 | | | | | | |
| Example 5 | | 1.46 | 0.20 | 0.25 | 1.58 | 0.77 |
| Example 6 | | 1.80 | 0.26 | 0.28 | 1.99 | 0.78 |
| Example 7 | | 1.92 | 0.34 | 0.37 | 2.05 | 0.84 |
| Comparative | 18 | 1.20 | 0.11 | 0.17 | 1.32 | 0.47 |
| Example 5 | | | | | | |
| Comparative | | 1.16 | 0.14 | 0.20 | 1.21 | 0.52 |
| Example 6 | | | | | | |
| Example 8 | | 1.31 | 0.18 | 0.25 | 1.35 | 0.72 |
| Example 9 | | 1.69 | 0.25 | 0.32 | 1.82 | 0.76 |
| Example 10 | | 1.87 | 0.36 | 0.40 | 1.96 | 0.81 |
| Comparative | | 2.05 | 0.42 | 0.48 | 2.14 | 0.84 |
| Example 7 | | | | | | |
| Comparative | 35 | 1.25 | 0.13 | 0.18 | 1.36 | 0.42 |
| Example 8 | | | | | | |
| Comparative | | 1.13 | 0.15 | 0.22 | 1.20 | 0.57 |
| Example 9 | | | | | | |
| Example 11 | | 1.43 | 0.20 | 0.27 | 1.52 | 0.72 |
| Example 12 | | 1.72 | 0.22 | 0.25 | 1.88 | 0.78 |
| Example 13 | | 1.80 | 0.34 | 0.39 | 1.95 | 0.83 |
| Example 14 | | 1.93 | 0.39 | 0.45 | 2.02 | 0.76 |
| Comparative | | 2.10 | 0.45 | 0.50 | 2.18 | 0.80 |
| Example 10 | | | | | | |

TABLE 4

| | Insertion | Insertion | Insertion | Tensile | |
|---|---|---|---|---|---|
| | Loss | Loss | Loss | Strength | Ma- |
| Category | (5 Hz) | (10 Hz) | (20 Hz) | (MPa) | chinability |
| Comparative | −3.35 | −5.86 | −10.30 | 167 | X |
| Example 1 | | | | | |
| Comparative | −3.51 | −6.12 | −11.12 | 154 | X |
| Example 2 | | | | | |
| Example 1 | −3.06 | −5.26 | −9.61 | 198 | ◯ |
| Example 2 | −3.15 | −5.57 | −9.83 | 204 | ⊚ |
| Example 3 | −3.35 | −6.09 | −10.15 | 205 | ⊚ |
| Example 4 | −3.82 | −6.91 | −11.94 | 210 | ⊚ |
| Comparative | −3.50 | −6.04 | −10.96 | 212 | X |
| Example 3 | | | | | |
| Comparative | −3.11 | −5.46 | −9.76 | 215 | X |
| Example 4 | | | | | |
| Example 5 | −3.03 | −5.24 | −9.20 | 207 | ⊚ |
| Example 6 | −3.21 | −5.68 | −10.08 | 206 | ⊚ |
| Example 7 | −3.97 | −7.03 | −12.42 | 217 | ⊚ |
| Comparative | −3.17 | −5.49 | −9.90 | 153 | X |
| Example 5 | | | | | |
| Comparative | −3.47 | −5.98 | −11.01 | 161 | X |
| Example 6 | | | | | |
| Example 8 | −2.82 | −5.20 | −9.05 | 209 | ⊚ |
| Example 9 | −2.99 | −5.25 | −9.15 | 212 | ⊚ |
| Example 10 | −4.06 | −7.07 | −12.98 | 210 | ⊚ |
| Comparative | −4.18 | −7.15 | −13.27 | 211 | ⊚ |
| Example 7 | | | | | |
| Comparative | −3.53 | −6.17 | −11.25 | 170 | X |
| Example 8 | | | | | |
| Comparative | −3.22 | −5.72 | −10.57 | 174 | X |
| Example 9 | | | | | |
| Example 11 | −2.86 | −5.31 | −8.86 | 204 | ⊚ |
| Example 12 | −3.07 | −5.29 | −9.20 | 206 | ⊚ |
| Example 13 | −3.35 | −5.84 | −10.30 | 207 | ⊚ |
| Example 14 | −4.25 | −7.20 | −13.10 | 202 | ⊚ |
| Comparative | −4.36 | −7.31 | −13.54 | 212 | ⊚ |
| Example 10 | | | | | |

As shown in Tables 3 and 4, when the thickness of the copper foil belonged to the scope of the present invention, and the ten-point mean roughness and the arithmetic mean roughness of the copper layer were controlled so as to belong to the scope of the present invention (Examples 1 to 14), it was seen that adhesion strength with the resin layer laminated thereon was very high, and a low insertion loss was exhibited even when high frequency electric signals were transmitted. Especially, the copper foils of Examples 1 to 3, 5, 6, 8, 9 and 11 to 13 have excellent adhesion strength with a resin laminated thereon, tensile strength, machinability and electrical properties with very low insertion losses.

Meanwhile, when the thickness of the copper foil belonged to the scope of the present invention, however, any one of the roughness was less than the scope of the present invention, adhesion strength was seen to significantly decrease, and when the roughness was greater than the scope of the present invention, an insertion loss was identified to be too high. In addition, when the adhesion strength was less than the scope of the present invention, tensile strength and machinability were seen to significantly decrease.

As described above, by controlling the mean roughness of the copper layer in the present invention, adhesion strength between the copper layer and the resin layer may be enhanced and an insertion loss may be lowered, and furthermore, by controlling the adhesion strength between the copper layer and the resin layer to a specific range, excellent tensile strength and machinability may be secured.

### Test Example 2

On each of the surface treated copper foils of Examples 11 and 15, the thermosetting resin composition of Table 2 was coated, and the result was dried for approximately 3 minutes to 10 minutes at 165° C. After that, for the resin layer-formed copper foil, floating was carried out at Solder 288° C. in accordance with the IPC TM-650 2. 4. 13 evaluation rule, and the time taken until separation between the resin layer and the copper foil was measured and evaluated. The results are shown in the following Table 4.

TABLE 4

| Category | Example 11 | Example 15 |
|---|---|---|
| Heat Resistance | >10 min | >10 min |
| (S/F, (@288° C.) | | |

As shown in Table 4, it was identified that excellent heat resistance was exhibited when the composition according to the present invention was coated on the surface treated copper foil according to the present invention.

The copper-clad laminate provided in the present invention has advantages in that, by controlling a thickness, roughness and the like of a copper layer included therein, adhesion strength with a resin layer laminated on the copper layer is enhanced, and an insertion loss is very much lowered to enhance electrical properties.

1. A copper-clad laminate comprising at least one of a copper layer having a roughened surface which is obtained by roughening at least one surface of a base copper layer so as to have a low profile, comprising a copper layer having a thickness of from 5 μm to 70 μm and a resin layer on the copper layer,
wherein a peeling strength between the copper layer and the resin layer is more than 0.6 N/mm when the thickness of the copper layer is more than 5 μm,
wherein a ten-point mean roughness Sz of the roughened surface is lower than that of the base copper layer.

2. The copper-clad laminate of claim 1, wherein the copper layer comprises a copper foil.

3. The copper-clad laminate of claim 2, further comprising a copper plated layer on one surface of the copper foil.

4. The copper-clad laminate of claim 1, wherein the ten-point mean roughness Sz of the roughened surface of the copper layer is below 2.0 μm.

5. The copper-clad laminate of claim 1, wherein an arithmetic mean roughness Sa of the roughened surface of the copper layer is below 0.4 μm.

6. The copper-clad laminate of claim 1, wherein the base copper layer has a matte side and an opposite shiny side, wherein the roughening may be conducted on the matte side of the base copper layer.

7. (canceled)

8. The copper-clad laminate of claim 6, wherein an arithmetic mean roughness Sa of the roughened matte side of the copper layer may be lower than that of the shiny side of the copper layer.

9. The copper-clad laminate of claim 6, wherein an arithmetic mean roughness Sa of the roughened matte side of the copper layer is below 0.4 μm.

10. The copper-clad laminate of claim 1, wherein the copper layer exhibits an insertion loss of from −3.60 dB to −2.50 dB when measured at a frequency of 5 GHz.

11. The copper-clad laminate of claim 1, wherein the copper layer exhibits an insertion loss of from −6.50 dB to −5.00 dB when measured at a frequency of 10 GHz.

12. The copper-clad laminate of claim 1, wherein the copper layer exhibits an insertion loss of from −8.50 dB to −6.75 dB when measured at a frequency of 15 GHz.

13. The copper-clad laminate of claim 1, wherein the copper layer exhibits an insertion loss of from −11.70 dB to −8.55 dB when measured at a frequency of 20 GHz.

14. The copper-clad laminate of claim 1, wherein a particle size of roughened particles of the roughened surface of the copper layer is from 0.1 μm to 2.0 μm.

15. The copper-clad laminate of claim 14, wherein a height of projections formed of the roughened particles of the roughened surface is from 1.0 μm to 5.0 μm.

16. The copper-clad laminate of claim 1, wherein the resin layer comprises a thermosetting composition comprising (a) polyphenylene ether or oligomer thereof having at least two unsaturated functional groups which are selected from the group consisting of vinyl group and allyl group at both molecular chain ends; (b) at least three kinds of cross-linkable curing agents; and (c) a flame-retardant.

17. The copper-clad laminate of claim 16, wherein the polyphenylene ether is represented by the following Chemical Formula 1: 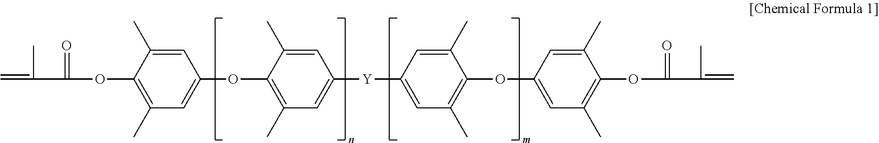
wherein, in Chemical Formula 1,
Y is at least one compound selected from the group consisting of bisphenol-A based compound, bisphenol-F based compound, bisphenol-S based compound, naphthalene based compound, anthracene based compound, biphenyl based compound, tetramethyl biphenyl based compound, phenol novolac based compound, cresol novolac based compound, bisphenol-A novolac based compound, and bisphenol-S novolac based compound,
m and n are integers independently selected from 3 to 20.

18. The copper-clad laminate of claim 16, wherein the cross-linkable curing agents comprise a composition comprising a hydrocarbon based curing agent (b1), a curing agent having at least three functional groups (b2) and a block-structured rubber.

19. The copper-clad laminate of claim 1, wherein the copper layer additionally comprises at least one layer selected from the group consisting of a heat-resistant layer, an anti-corrosive layer, a chromate layer and a silane coupling layer on the resin layer.

20. The copper-clad laminate of claim 2, wherein the copper foil is an electrodeposited copper foil.

21. A printed circuit board comprising the copper-clad laminate of claim 1.
